(19) United States
(12) Patent Application Publication
(10) Pub. No.: US 2006/0208267 A1
(43) Pub. Date: Sep. 21, 2006

(54) Side-emitting solid-state semiconductor light emitting device

(75) Inventors: Yuan-Cheng Chin, Hsintien City (TW); Hung-Chih Li, Taichung City (TW)

Correspondence Address: TROXELL LAW OFFICE PLLC;SUITE 1404, 5205 LEESBURG PIKE, FALLS CHURCH, VA, 22041, US

(73) Assignee: Unity Opto Technology Co., Ltd. & Genius Electronic Optical Co., Ltd.

(21) Appl. No.: 11/079,255

(22) Filed: Mar. 15, 2005

(51) Int. Cl. H01L 29/18

(52) U.S. Cl. 257/98

(57) ABSTRACT

A side-emitting solid-state semiconductor light emitting device (light emitting diode) comprises a light emitting diode package and a lens, wherein the lens is mounted on the front surface of the light emitting diode package to receive the light emitted from the light emitting diode and redirect the received light by use of a reflecting part to project the light on the peripheral surface of the light emitting diode package. This peripheral surface is designed to provide various changes and the side-emitting light is changed according to the changes of the peripheral surface.

### FIELD OF THE INVENTION

The present invention relates to an improved structure of a side-emitting solid-state semiconductor light emitting device, and more particularly to a structure for redirecting the path of the light emitted from the light emitting diode by use of the lens and the redirected light is further changed-according to the changes of the periphery of the lens, and this structure is suitable for the marketplaces, all kinds of advertising billboards, backlight sources, or the likes.

### BACKGROUND OF THE INVENTION

The light emitted from a conventional light emitting diode is the forward-emitting light and the light emitting diode is coupled with a printed circuit board to assign the emitting direction of the light. The simplest method is to change the mounting position of the printed circuit board. For example, the printed circuit board is mounted vertically in the machine to emit the side-emitting light or the printed circuit board is mounted on the top of the machine to emit the downward-emitting light.

As shown in FIG. 1, Taiwan Pat. No. 433,552, entitled “side-emitting light emitting diode apparatus”, discloses another improving method and comprises a first pin A having a light condensing ring A1 on the upper end of the first pin A for holding a light emitting diode C and providing an upwardly-faced light emitting opening; a second pin B, the upper end of the second pin B being spaced at a proper distance from the upper end of the first pin A; the light emitting diode C fixed in the light condensing ring A1; a transparent adhesive D for covering the light condensing ring A1, the light emitting diode C, and the upper portions of the first pin A and the second pin B and exposing the lower portions of the first pin A and the second pin B, wherein the outer surface of the shaped transparent adhesive D includes a convex sphere D1. The lower portions of the first pin A and the second ping B can be bent to form their respective bending part E. Therefore, the light emitted from chip is side-emitted outwardly from the light emitting opening and the transparent adhesive D to form a better side-emitting light emitting diode apparatus and decrease the cost of the molding process significantly.

In brief, the pins of the light emitting diode of the above-mentioned patent are bent to provide with a bending angle such that the former forward-emitting light is changed to the side-emitting light. The aforementioned method only changes the angle and the mounting position of the light emitting diode so as to provide the user with the required light emitting direction, but the emitted light does not equipped with more special changes. Consequentially, it still not meets the user requirement for the practical usage.

### SUMMARY OF THE INVENTION

The main object of the present invention is to provide an improved structure of a side-emitting solid-state semiconductor light emitting device for redirecting the light emitted from a light emitting diode by combining the light emitting diode with a lens without changing the angles and the mounting positions of the pins thereby providing a superior side-emitting light source, and the side-emitting light is further changed by modifying the peripheral surface of the lens to enhance its practicability.

In order to achieve the aforementioned object, the present invention discloses a light emitting diode package and a lens, wherein the lens is mounted on the front surface of the light emitting diode package to receive the light emitted from the light emitting diode and redirect the received light by use of a reflecting part to project the light on the peripheral surface of the light emitting diode package. This peripheral surface is designed to provide with various changes such as a convex surface or a concave surface and the side-emitting light is changed according to the changes of the peripheral surface.

The other features and preferred embodiments of the present invention will now be described with reference to the accompanying drawings.

### BRIEF DESCRIPTION OF THE DRAWINGS

FIG. 1 is a schematic cross-section view showing the conventional side-emitting light emitting diode.

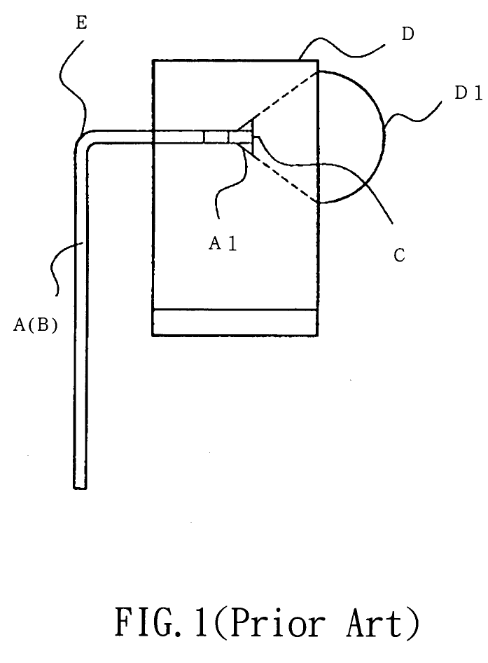

FIG. 2 is an elevational view showing the outward appearance of the preferred embodiment of the present invention.

FIG. 3 is a schematic cross-section view showing the preferred embodiment of the present invention.

FIG. 4 is a schematic cross-section view showing the elevational appearance of a first example of the preferred embodiment of the present invention.

FIG. 5 is a schematic view showing the light path in accordance with the first example shown in the FIG. 4.

FIG. 6 is a schematic cross-section view showing the elevational appearance of a second example of the preferred embodiment of the present invention.

FIG. 7 is a schematic view showing the light path in accordance with the second example shown in the FIG. 6.

### DETAILED DESCRIPTION OF THE PREFERRED EMBODIMENT

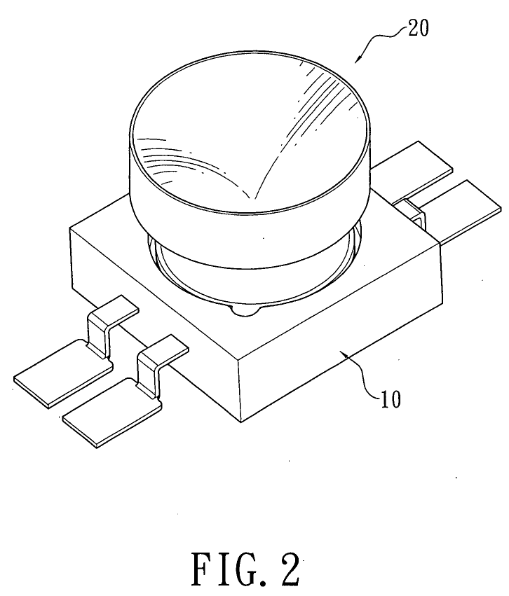

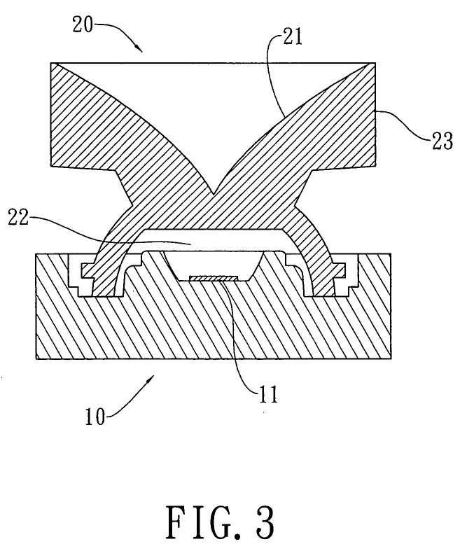

Referring to FIG. 2 and FIG. 3 simultaneously, a side-emitting solid-state semiconductor light emitting device of the present invention comprises a light emitting diode package 10 and a lens 20, wherein the lens 20 covers a chip 11 of the light emitting diode package 10 from top to toe to complete the assembly. The lens 20 is roughly a cylinder having a concave holding room 22 on its bottom to hold the chip 11 of the light emitting diode package 10, and the top of the lens 20 is concaved gradually from the periphery to the center to form a concave surface and this concave surface is designed to be a reflecting part 21. The outer periphery of the top of the lens 20 (i.e. the concave surface) constitutes a projecting part 23, wherein the projecting part 23 is a flat surface for emitting the light outward uniformly. Accordingly, the light emitted upwardly from the chip 11 is reflected by the reflecting part 21 of the lens 20 and the reflected light is side-emitted outward uniformly from projecting part 23 thereby changing the forward-emitting light into the side-emitting light.

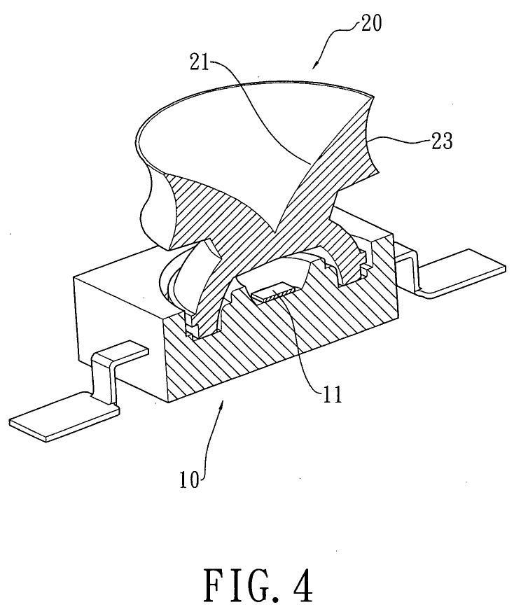

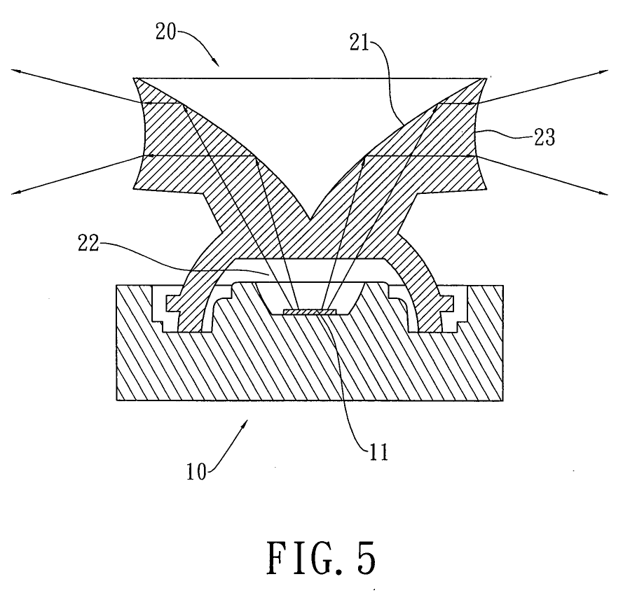

Referring to FIG. 4, a first example of the present invention is shown. The lens 20 is still a cylinder and includes the holding room 22 on the bottom of the lens 20 for covering the chip 11 of the light emitting diode package 10 and the reflecting part 21 concaved gradually from the periphery to the center on the top of the lens 20. The projecting part 23 is changed from the flat surface to a concave surface such that the light emitted upwardly from the chip 11 is reflected by the reflecting part 21 of the lens 20 and side-emitted outwardly from projecting part 23. As shown in FIG. 5, the projecting part 23 is a concave lens for scattering light since the projecting part 23 is designed to be the concave surface. Accordingly, the side-emitting light is provided with more changes to enhance its practicability.

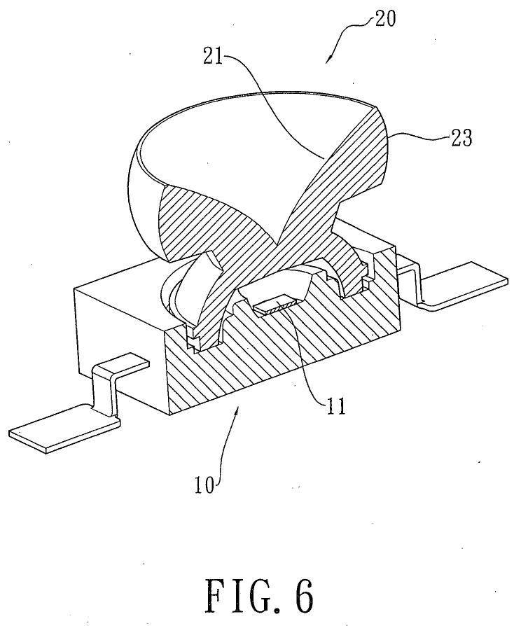

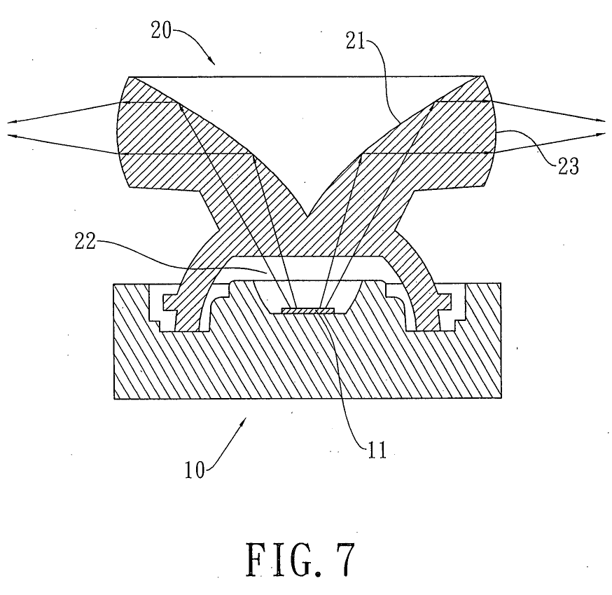

Referring further to FIG. 6 and FIG. 7, the projecting part 23 of the lens 20 of the present invention is changed from the flat surface to a convex surface. The forward-emitting light is emitted from the chip 11 and reflected by the reflecting part 21 to form the side-emitting light when it is in use. The side-emitting light is then emitted through the convex projecting part 23 to focus the light as if a convex lens focuses it. Accordingly, the emitting light has a focal point.

As described above, the apparatus of the present invention provides the following advantages.

1. The forward-emitting light emitted from the light emitting diode is redirected to the side-emitting light without changing the angles and the mounting positions of the pins thereby providing a superior side-emitting light source.

2. The reflecting part of the lens changes the forward-emitting light emitted from the chip into the side-emitting light, and more practicabilities are provided by, for example, changing the projecting part from the flat surface to the concave surface for scattering the light or the convex surface for focusing the light.

However, the above description merely illustrates the preferred embodiments of the present invention, and the applicable scope of the present invention is not limited hereto. Any obvious modification and revision made by a person skilled in the art are included within the spirit and scope of the present invention.

As described above, the present invention is able to achieve the expected purpose of the present invention by providing with a side-emitting solid-state semiconductor light emitting device. The application that complies with utility is therefore submitted for a patent.

What the invention claimed is:

1. A side-emitting solid-state semiconductor light emitting device comprising:
a light emitting diode package comprising a base having pins, a chip being coupled with the base; and
a lens having a holding room on the bottom thereof, the top of the lens being concaved gradually from the periphery to the center thereof to form a first concave surface, the first concave surface being designed to be a reflecting part, and a projecting part being constituted by the periphery of the lens, wherein the lens is coupled with the base to cover the chip by the holding room and the forward-emitting light emitted from the chip is reflected by the reflecting part and redirected for side-emitting the light from the projecting part thereby providing a superior side-emitting light source.

2. The side-emitting solid-state semiconductor light emitting device of claim 1, wherein the projecting part of the lens is a flat surface for emitting the light uniformly.

3. The side-emitting solid-state semiconductor light emitting device of claim 1, wherein the projecting part of the lens is a second concave surface for scattering the light.

4. The side-emitting solid-state semiconductor light emitting device of claim 1, wherein the projecting part of the lens is a convex surface for focusing the light.
